(19) United States
(12) Patent Application Publication
(10) Pub. No.: US 2016/0322115 A1
(43) Pub. Date: Nov. 3, 2016

(54) Shift Register Unit, Driving Method Thereof, Gate Driving Circuit and Display Apparatus

(71) Applicants: BOE Technology Group Co., Ltd., Beijing (CN); Hefei BOE Optoelectronics Technology Co., Ltd., Anhui (CN)

(72) Inventors: Fei Xu, Beijing (CN); Lei Lv, Beijing (CN); Jun Hong, Beijing (CN)

(21) Appl. No.: 15/078,513

(22) Filed: Mar. 23, 2016

(30) Foreign Application Priority Data
Apr. 29, 2015 (CN) 201510212465.8

(51) Int. Cl. G11C 19/28; G09G 3/36

(52) U.S. Cl. CPC G11C 19/28; G09G 3/3685; G09G 3/3696; G09G 2310/0286; G09G 2310/0289

(57) ABSTRACT

Provided are a shift register unit, driving method thereof, a gate driving circuit and a display apparatus. The shift register unit comprises an input unit, a reset unit, a first output unit, a second output unit and a control unit. The shift register unit uses the control unit to control the levels of the first node and the second node, ensuring that the gate signal output terminal of the shift register unit can always output signals, which can thus eliminate noises and ensure the stability of signals output by the gate signal output terminal.

This application claims priority to and the benefit of Chinese Patent Application No. 201510212465.8 filed on Apr. 29, 2015, which application is incorporated herein in its entirety.

### TECHNICAL FIELD OF THE DISCLOSURE

The present disclosure relates to a shift register unit, driving method thereof, a gate driving circuit and a display apparatus.

### BACKGROUND

In a thin film transistor (TFT) display, usually, a gate driving device provides gate driving signals to gates of TFTs in a pixel area. The gate driving device can be formed on an array substrate of a liquid crystal display (LCD) by an array process, i.e., a gate driver on array (GOA) process. Such an integration process not only reduces cost, but also can achieve a beautiful design in which two sides of the liquid crystal panel are symmetric. At the same time, it saves wiring space of fan-out and bonding area of a gate integrated circuit (IC) such that a design of narrow frame can be achieved. In addition, such an integration process can save bonding process in the gate scan line direction so as to improve productivity and yield.

Currently, in existing gate driving circuits, mostly, one clock signal is used to control a pull-down node which is then used to control the pull-down of a pull-up node and a gate signal output terminal. However, the duty ratio of the pull-down node is 50%; therefore, the gate signal output terminal Output is pulled down during half time of a scan period, and is floated during the other half time, such that the noise of signals output by the gate signal output terminal is large.

### SUMMARY

At least one embodiment of the present disclosure provides a shift register unit, driving method thereof, a gate driving circuit and a display apparatus, which can reduce noise of signals output by the gate signal output terminal of the shift register unit.

At least one embodiment of the present disclosure provides a shift register unit comprising an input unit, a reset unit, a first output unit, a second output unit and a control unit, wherein

a first input terminal of the input unit is configured to receive an input signal, a second input terminal of the input unit is connected with a first reference voltage, and an output terminal of the input unit is connected to a first node, the input unit is configured to supply the first reference voltage to the first node under the control of the input signal;

a first input terminal of the reset unit is configured to receive a reset signal, a second input terminal of the reset unit is connected with a second reference voltage, and an output terminal of the reset unit is connected to the first node, the reset unit is configured to supply the second reference voltage to the first node under the control of the reset signal;

a first input terminal of the first output unit is configured to receive a clock signal, a second input terminal of the first output unit is connected to the first node, and an output terminal of the first output unit is connected to a gate signal output terminal of the shift register unit, the first output unit is configured to supply the clock signal to the gate signal output terminal of the shift register unit when the level of the first node is a first level;

a first input terminal of the second output unit is connected to a first DC source, a second input terminal of the second output unit is connected to a second node, a first output terminal of the second output unit is connected to the first node, and a second output terminal of the second output unit is connected to the gate signal output terminal of the shift register unit, the second output unit is configured to supply the voltage of the first DC source to the first node and the gate signal output terminal of the shift register unit respectively when the level of the second node is the first level;

an input terminal of the control unit is connected to the first node and an output terminal of the control unit is connected to the second node, the control unit is configured to make the level of the first node be a second level when the level of the second node is the first level and make the level of the second node be the second level when the level of the first node is the first level.

When the first level is a high level and the second level is a low level, the first reference voltage is a high level voltage, and the second reference voltage and the voltage of the first DC source are low level voltages; or when the first level is a low level and the second level is a high level, the first reference voltage is a low level voltage, and the second reference voltage and the voltage of the first DC source are high level voltages.

Optionally, in order to diminish distortion of signals output by the gate signal output terminal, the above shift register unit provided by at least one embodiment of the present disclosure further comprises a third output unit.

A first input terminal of the third output unit is connected to a second DC source, a second input terminal of the third output unit is connected to the output terminal of the first output unit, and an output terminal of the third output unit is connected to the gate signal output terminal of the shift register unit.

The third output unit is configured to supply the voltage of the second DC source to the gate signal output terminal of the shift register unit when the voltage of the output terminal of the first output unit is the first level.

When the first level is a high level and the second level is a low level, the voltage of the second DC source is a high level voltage; when the first level is a low level and the second level is a high level, the voltage of the second DC source is a low level voltage.

In a possible implementation, in the above shift register unit provided by at least one embodiment of the present disclosure, the third output unit comprises a first switch transistor whose gate is the second input terminal of the third output unit, whose source is the first input terminal of the third output unit and whose drain is the output terminal of the third output unit.

Optionally, in order to relieve the unfavorable problems such as shutdown after-imaging of the display apparatus, the above shift register unit provided by at least one embodiment of the present disclosure further comprises a discharging unit.

A first input terminal of the discharging unit is connected to a third DC source, a second input terminal of the discharging unit is connected with a discharging control signal, and an output terminal of the discharging unit is connected to the gate signal output terminal.

The discharging unit is configured to supply the voltage of the third DC source to the gate signal output terminal under the control of the discharging control signal.

In a possible implementation, in the above shift register unit provided by at least one embodiment of the present disclosure, the discharging unit comprises a second switch transistor whose gate is the second input terminal of the discharging unit, whose source is the first input terminal of the discharging unit and whose drain is the output terminal of the discharging unit.

In a possible implementation, in the above shift register unit provided by at least one embodiment of the present disclosure, the input unit comprises a third switch transistor whose gate is the first input terminal of the input unit, whose source is the second input terminal of the input unit and whose drain is the output terminal of the input unit.

In a possible implementation, in the above shift register unit provided by at least one embodiment of the present disclosure, the reset unit comprises a fourth switch transistor whose gate is the first input terminal of the reset unit, whose source is the second input terminal of the reset unit and whose drain is the output terminal of the reset unit.

In a possible implementation, in the above shift register unit provided by at least one embodiment of the present disclosure, the first output unit comprise a fifth switch transistor and a capacitor, wherein

a gate of the fifth switch transistor is the second input terminal of the first output unit, a source of the fifth switch transistor is the first input terminal of the first output unit, and a drain of the fifth switch transistor is the output terminal of the first output unit; and

the capacitor is connected between the gate and the drain of the fifth switch transistor.

In a possible implementation, in the above shift register unit provided by at least one embodiment of the present disclosure, the second output unit comprises a sixth switch transistor and a seventh switch transistor, wherein

a gate of the sixth switch transistor is the second input terminal of the second output unit, a source of the sixth switch transistor is the first input terminal of the second output unit, and a drain of the sixth switch transistor is the first output terminal of the second output unit; and

a gate of the seventh switch transistor is the second input terminal of the second output unit, a source of the seventh switch transistor is the first input terminal of the second output unit, and a drain of the seventh switch transistor is the second output terminal of the second output unit.

In a possible implementation, in the above shift register unit provided by at least one embodiment of the present disclosure, the control unit comprises an eighth switch transistor, a ninth switch transistor, a tenth switch transistor and an eleventh switch transistor, wherein

a gate of the eighth switch transistor and a gate of the ninth switch transistor are connected both as the input terminal of the control unit, a source of the eighth switch transistor is connected to a source of the ninth switch transistor and the first DC source respectively, and a drain of the eighth switch transistor is connected to a drain of the tenth switch transistor and is the output terminal of the control unit;

a drain of the ninth switch transistor is connected to a gate of the tenth switch transistor and a drain of the eleventh switch transistor respectively;

a source of the tenth switch transistor is connected to a source of the eleventh switch transistor, a gate of the eleventh switch transistor and a fourth DC source respectively.

Accordingly, at least one embodiment of the present disclosure also provides a driving method of any shift register unit as described in the above, comprising:

at a first phase, the input unit supplying the first reference voltage to the first node under the control of the input signal; the level of the first node being the first level, and the control unit making the level of the second node be the second level; the first output unit supplying the clock signal to the gate signal output terminal of the shift register unit;

at a second phase, the level of the first node being the first level, and the control unit making the level of the second node be the second level; the first output unit supplying the cock signal to the gate signal output terminal of the shift register unit;

at a third phase, the reset unit supplying the second reference voltage to the first node under the control of the reset signal; the level of the second node being the first level, and the control unit making the level of the first node be the second level; the second output unit supplying the voltage of the first DC source to the first node and the gate signal output terminal of the shift register unit respectively; and

at a fourth phase, the level of the second node being the first level, and the control unit making the level of the first node be the second level; the second output unit supplying the voltage of the first DC source to the first node and the gate signal output terminal of the shift register unit respectively.

Accordingly, at least one embodiment of the present disclosure also provides a gate driving circuit comprising multiple shift register units of any above-described type provided by embodiments of the present disclosure which are connected in series; wherein

except the first stage of shift register unit, the gate signal output terminal of each stage of shift register unit inputs a reset signal to its adjacent previous stage of shift register unit;

except the last stage of shift register unit, the gate signal output terminal of each stage of shift register unit inputs an input signal to its adjacent next stage of shift register unit; and

the input signal of the first stage of shift register unit is input by a frame start signal terminal.

Accordingly, at least one embodiment of the present disclosure also provides a display apparatus comprising any above-described gate driving circuit provided by embodiments of the present disclosure.

Embodiments of the present disclosure provide a shift register unit, driving method thereof, a gate driving circuit and a display apparatus. The shift register unit comprises an input unit, a reset unit, a first output unit, a second output unit and a control unit. The input unit is configured to supply a first reference voltage to a first node under the control of an input signal; the reset unit is configured to supply a second reference voltage to the first node under the control of a reset signal; the first output unit is configured to supply a clock signal to the gate signal output terminal of the shift register unit when the level of the first node is a first level; the second output unit is configured to supply the voltage of a first DC source to the first node and the gate signal output terminal of the shift register unit respectively when the level of a second node is the first level; the control unit is configured to make the level of the first node be a second level when the level of the second node is the first level and make the level of the second node be the second level when the level of the first node is the first level. The shift register unit uses the control unit to control the levels of the first node and the second node. When the level of the first node is the first level, the first output unit supplies the clock signal to the gate signal output terminal of the shift register unit, and when the level of the second node is the first level, the second output unit supplies the voltage of the first DC source to the first node and the gate signal output terminal of the shift register unit respectively, so as to release noise for the first node and the gate signal output terminal and further ensure that the gate signal output terminal of the shift register unit can always output signals, which can thus eliminate noises and ensure the stability of signals output by the gate signal output terminal.

### BRIEF DESCRIPTION OF THE DRAWINGS

FIG. 1 is a schematic diagram of structure of a shift register unit provided by an embodiment of the present disclosure;

FIG. 2 is a schematic diagram of structure of a shift register unit provided by an embodiment of the present disclosure;

FIG. 3 is a schematic diagram of structure of a shift register unit provided by an embodiment of the present disclosure;

FIG. 4a is a schematic diagram of structure of a shift register unit provided by an embodiment of the present disclosure with all transistors being N type transistors;

FIG. 4b is a schematic diagram of structure of a shift register unit provided by an embodiment of the present disclosure with all transistors being P type transistors;

FIG. 5a is a schematic diagram of structure of a shift register unit provided by an embodiment of the present disclosure with all transistors being N type transistors;

FIG. 5b is a schematic diagram of structure of a shift register unit provided by an embodiment of the present disclosure with all transistors being P type transistors;

FIG. 6a is a circuit time sequence diagram during forward scan of a shift register shown in FIG. 5a;

FIG. 6b is a circuit time sequence diagram during reverse scan of a shift register shown in FIG. 5a;

FIG. 6c is a circuit time sequence diagram during forward scan of a shift register shown in FIG. 5b;

FIG. 6d is a circuit time sequence diagram during reverse scan of a shift register shown in FIG. 5b;

FIG. 7a is a schematic diagram of structure of a shift register unit provided by an embodiment of the present disclosure with all transistors being N type transistors;

FIG. 7b is a schematic diagram of structure of a shift register unit provided by an embodiment of the present disclosure with all transistors being P type transistors;

FIG. 8 is a schematic diagram of structure of a gate driving circuit provided by an embodiment of the present disclosure;

FIG. 9 is a schematic flowchart of a driving method of a shift register unit provided by an embodiment of the present disclosure.

### DETAILED DESCRIPTION

In the following, specific implementations of shift register units, their driving methods, gate driving circuits and display apparatuses provided by embodiments of the present disclosure will be described in detail in connection with figures.

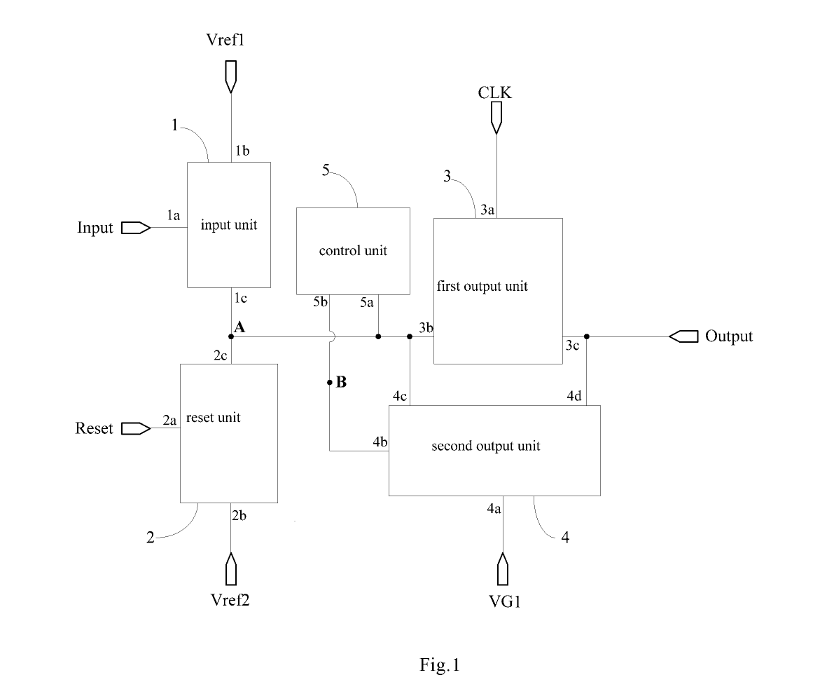

FIG. 1 is a schematic diagram of structure of a shift register unit provided by an embodiment of the present disclosure. As shown in FIG. 1, the shift register unit comprises an input unit 1, a reset unit 2, a first output unit 3, a second output unit 4 and a control unit 5.

A first input terminal 1a of the input unit 1 is configured to receive an input signal Input, its second input terminal 1b is connected with a first reference voltage Vref1, and its output terminal 1c is connected to a first node A; the input unit 1 is configured to supply the first reference voltage Vref1 to the first node A under the control of the input signal Input.

A first input terminal 2a of the reset unit 2 is configured to receive a reset signal Reset, its second input terminal 2b is connected with a second reference voltage Vref2, and its output terminal 2c is connected to the first node A; the reset unit 2 is configured to supply the second reference voltage Vref2 to the first node A under the control of the reset signal Reset.

A first input terminal 3a of the first output unit 3 is configured to receive a clock signal CLK, its second input terminal 3b is connected to the first node A, and its output terminal 3c is connected to a gate signal output terminal Output of the shift register unit; the first output unit 3 is configured to supply the clock signal CLK to the gate signal output terminal Output of the shift register unit when the level of the first node A is a first level.

A first input terminal 4a of the second output unit 4 is connected to a first DC source VG1, its second input terminal 4b is connected to a second node B, its first output terminal 4c is connected to the first node A, and its second output terminal 4d is connected to the gate signal output terminal Output of the shift register unit; the second output unit 4 is configured to supply the voltage of the first DC source VG1 to the first node A and the gate signal output terminal Output of the shift register unit respectively when the level of the second node B is the first level.

An input terminal 5a of the control unit 5 is connected to the first node A, and its output terminal 5b is connected to the second node B; the control unit 5 is configured to make the level of the first node A be a second level when the level of the second node B is the first level and make the level of the second node B be the second level when the level of the first node A is the first level.

When the first level is a high level and the second level is a low level, the first reference voltage is a high level voltage, and the second reference voltage and the voltage of the first DC source are low level voltages; or when the first level is a low level and the second level is a high level, the first reference voltage is a low level voltage, and the second reference voltage and the voltage of the first DC source are high level voltages.

The above shift register unit provided by an embodiment of the present disclosure comprises an input unit, a reset unit, a first output unit, a second output unit and a control unit. The input unit is configured to supply a first reference voltage to a first node under the control of an input signal; the reset unit is configured to supply a second reference voltage to the first node under the control of a reset signal; the first output unit is configured to supply a clock signal to the gate signal output terminal of the shift register unit when the level of the first node is a first level; the second output unit is configured to supply the voltage of a first DC source to the first node and the gate signal output terminal of the shift register unit respectively when the level of a second node is the first level; the control unit is configured to make the level of the first node be a second level when the level of the second node is the first level and make the level of the second node be the second level when the level of the first node is the first level. The shift register unit uses the control unit to control the levels of the first node and the second node, when the level of the first node is the first level, the first output unit supplies the clock signal to the gate signal output terminal of the shift register unit, and when the level of the second node is the first level, the second output unit supplies the voltage of the first DC source to the first node and the gate signal output terminal of the shift register unit respectively, so as to release noise for the first node and the gate signal output terminal and further ensure that the gate signal output terminal of the shift register unit can always output signals, which can thus eliminate noises and ensure the stability of signals output by the gate signal output terminal.

It is noted that the above shift register unit provided by an embodiment of the present disclosure is a bi-directional scan register. If the first level is a high level and the second level is a low level, then during forward scan, the first reference voltage is a high level voltage, and the second reference voltage is a low level voltage, and during reverse scan, the input signal is taken as the reset signal, the reset signal is taken as the input signal, the first reference voltage is a low level voltage, and the second reference voltage is a high level voltage. If the first level is a low level and the second level is a high level, then during forward scan, the first reference voltage is a low level voltage, and the second reference voltage is a high level voltage, and during reverse scan, the input signal is taken as the reset signal, the reset signal is taken as the input signal, the first reference voltage is a high level voltage, and the second reference voltage is a low level voltage.

In the following, detailed description will be made to the present disclosure in connection with exemplary embodiments. It is noted that the embodiments are for better explanation of the present disclosure, but not limiting of the present disclosure.

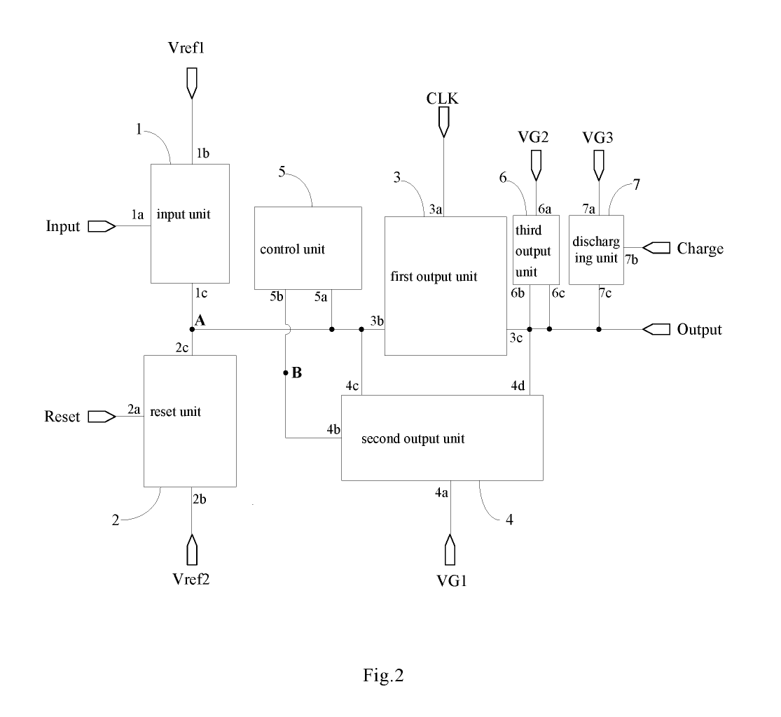

Optionally, the above shift register unit provided by an embodiment of the present disclosure, as shown in FIG. 2, can further comprise a third output unit 6.

For the third output unit 6, its first input terminal 6a is connected to a second DC source VG2, its second input terminal 6b is connected to the output terminal 3c of the first output unit 3, and its output terminal 6c is connected to the gate signal output terminal Output of the shift register unit.

The third output unit 6 is configured to supply the voltage of the second DC source VG2 to the gate signal output terminal Output of the shift register unit when the voltage of the output terminal 3c of the first output unit 3 is the first level.

When the first level is a high level and the second level is a low level, the voltage of the second DC source VG2 is a high level voltage; when the first level is a low level and the second level is a high level, the voltage of the second DC source VG2 is a low level voltage.

As such, when the voltage of the output terminal of the first output unit is the first level, the third output unit is used to supply the voltage of the second DC source to the gate signal output terminal of the shift register unit, reducing distortion of signals output by the gate signal output terminal and effectively relieving the problem of insufficient charging of high resolution products.

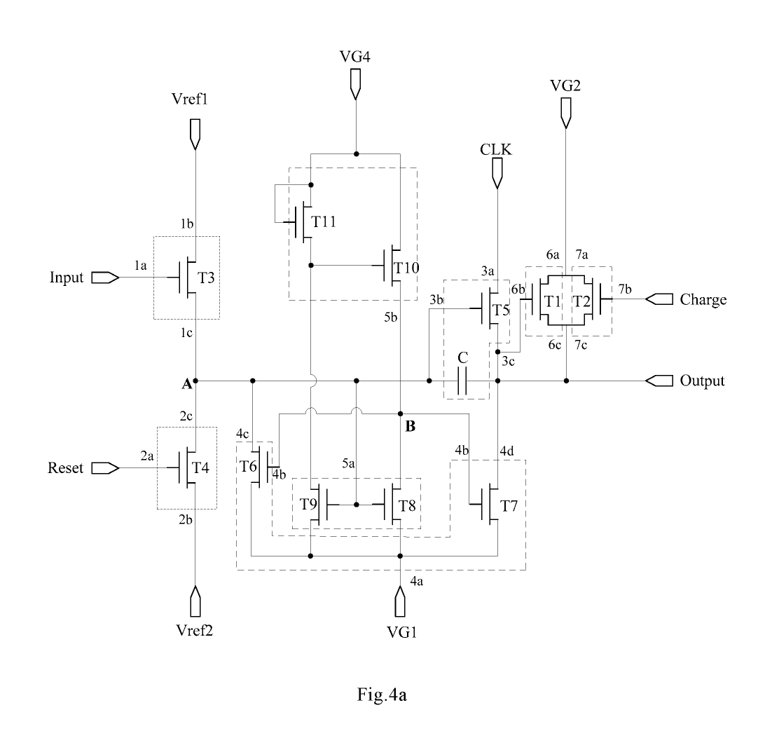

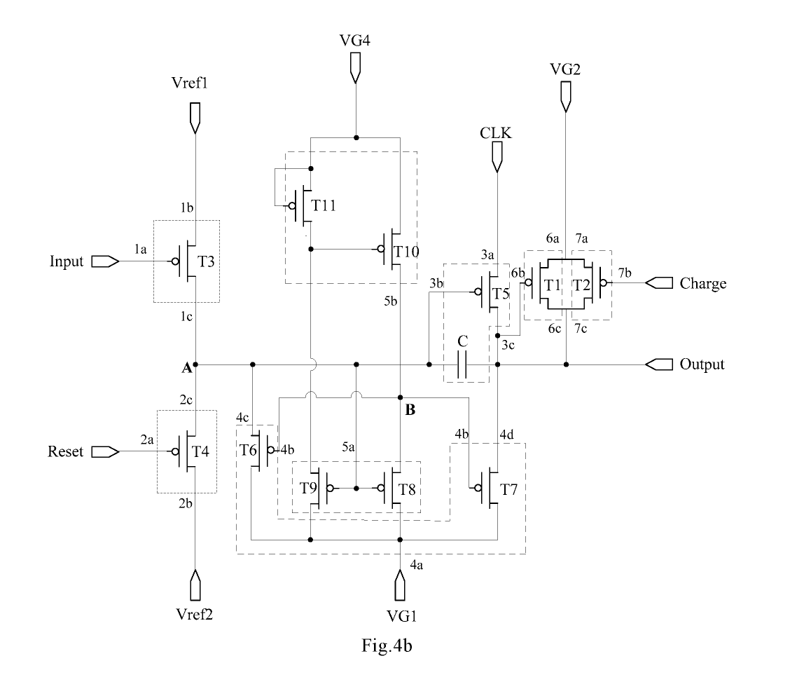

Optionally, in the above shift register unit provided by an embodiment of the present disclosure, as shown in FIG. 4a and FIG. 4b, the third output unit 6 can comprise a first switch transistor T1.

For the first switch transistor T1, its gate is the second input terminal of the third output unit, its source is the first input terminal of the third output unit, and its drain is the output terminal of the third output unit.

In implementation, as shown in FIG. 4a, the first switch transistor T1 can be an N type transistor, or as shown in FIG. 4b, the first switch transistor T1 can also be a P type transistor, which is not limited herein.

The above only exemplarily explains a structure of the third output unit in the shift register unit. In implementation, the structure of the third output unit is not limited to the above structure provided by the embodiment of the present disclosure, but can also be other structures known by those skilled in the art, which is not limited herein.

Optionally, the above shift register unit provided by an embodiment of the present disclosure, as shown in FIG. 2, can further comprise a discharging unit 7.

For the discharging unit 7, its first input terminal 7a is connected to a third DC source VG3, its second input terminal 7b is connected with a discharging control signal Charge, and its output terminal 7c is connected to the gate signal output terminal Output.

The discharging unit 7 is configured to supply the voltage of the third DC source VG3 to the gate signal output terminal Output under the control of the discharging control signal Charge.

In implementation, when the first level is a high level and the second level is a low level, the voltage of the third DC source is a high level voltage; when the first level is a low level and the second level is a high level, the voltage of the third DC source is a low level voltage. As such, the function that the discharging unit supplies the voltage of the third DC source to the gate signal output terminal under the control of the discharging control signal is used to realize self check function of pixel units connected to respective rows of gate lines. In addition, it is possible that the discharging unit supplies the voltage of the third DC source to the gate signal output terminal before the display apparatus is shut down to turn on all the gate lines for discharging, effectively relieving the unfavorable problems such as shutdown after-imaging of the display apparatus.

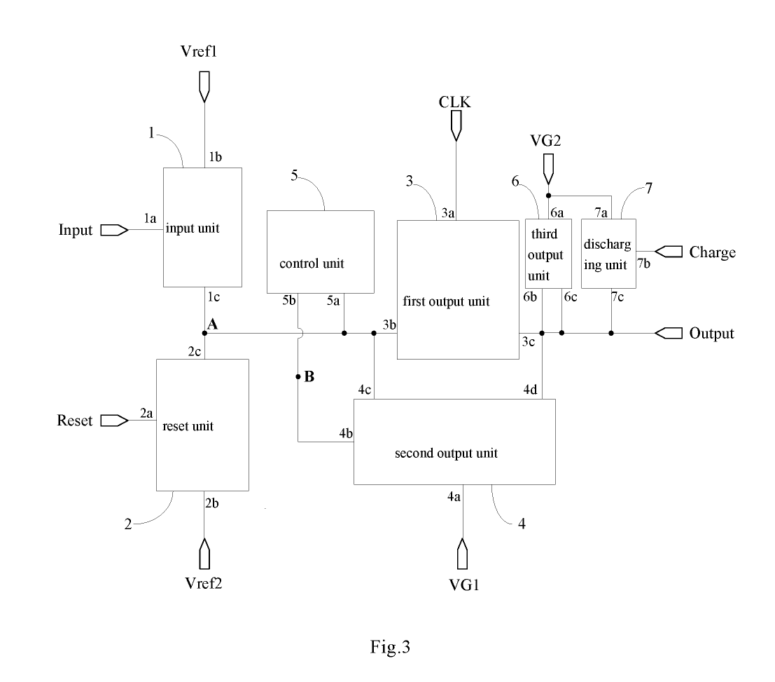

Optionally, in implementation, in the above shift register units provided by an embodiment of the present disclosure, as shown in FIG. 3, the second DC source VG2 is the third DC source VG3, in other words, the second DC source VG2 and the third DC source VG3 are connected to the same power source terminal.

Optionally, in implementation, in a shift register unit provided by an embodiment of the present disclosure, as shown in FIG. 4a and FIG. 4b, the discharging unit 7 can comprise a second switch transistor T2.

For the second switch transistor T2, its gate is the second input terminal 7b of the discharging unit 7, its source is the first input terminal 7a of the discharging unit 7, and its drain is the output terminal 7c of the discharging unit 7.

In implementation, as shown in FIG. 4a, the second switch transistor T2 can be an N type transistor, or as shown in FIG. 4b, the second switch transistor T2 can also be a P type transistor, which is not limited herein.

The above only exemplarily explains a structure of the discharging unit in the shift register unit. In implementation, the structure of the discharging unit is not limited to the above structure provided by the embodiment of the present disclosure, but can also be other structures known by those skilled in the art, which is not limited herein.

Optionally, in implementation, in a shift register unit provided by an embodiment of the present disclosure, as shown in FIG. 4a and FIG. 4b, the input unit 1 can comprise a third switch transistor T3.

For the third switch transistor T3, its gate is the first input terminal 1a of the input unit 1, its source is the second input terminal 1b of the input unit 1, and its drain is the output terminal 1c of the input unit 1.

In implementation, as shown in FIG. 4a, the third switch transistor T3 can be an N type transistor, or as shown in FIG. 4b, the third switch transistor T3 can also be a P type transistor, which is not limited herein.

The above only exemplarily explains a structure of the input unit in the shift register unit. In implementation, the structure of the input unit is not limited to the above structure provided by the embodiment of the present disclosure, but can also be other structures known by those skilled in the art, which is not limited herein.

Optionally, in implementation, in a shift register unit provided by an embodiment of the present disclosure, as shown in FIG. 4a and FIG. 4b, the reset unit 2 can comprise a fourth switch transistor T4.

For the fourth switch transistor T4, its gate is the first input terminal 2a of the reset unit 2, its source is the second input terminal 2b of the reset unit 2, and its drain is the output terminal 2c of the reset unit 2.

In implementation, as shown in FIG. 4a, the fourth switch transistor T4 can be an N type transistor, or as shown in FIG. 4b, the fourth switch transistor T4 can also be a P type transistor, which is not limited herein.

The above only exemplarily explains a structure of the reset unit in the shift register unit. In implementation, the structure of the reset unit is not limited to the above structure provided by the embodiment of the present disclosure, but can also be other structures known by those skilled in the art, which is not limited herein.

Optionally, in implementation, in a shift register unit provided by an embodiment of the present disclosure, as shown in FIG. 4a and FIG. 4b, the first output unit 3 can comprise a fifth switch transistor T5 and a capacitor C.

For the fifth switch transistor T5, its gate is the second input terminal 3b of the first output unit 3, its source is the first input terminal 3a of the first output unit 3, and its drain is the output terminal 3c of the first output unit 3.

The capacitor C is connected between the gate and the drain of the fifth switch transistor T5.

In implementation, as shown in FIG. 4a, the fifth switch transistor T5 can be an N type transistor, or as shown in FIG. 4b, the fifth switch transistor T5 can also be a P type transistor, which is not limited herein.

The above only exemplarily explains a structure of the first output unit in the shift register unit. In implementation, the structure of the first output unit is not limited to the above structure provided by the embodiment of the present disclosure, but can also be other structures known by those skilled in the art, which is not limited herein.

Optionally, in implementation, in a shift register unit provided by an embodiment of the present disclosure, as shown in FIG. 4a and FIG. 4b, the second output unit 4 can comprise a sixth switch transistor T6 and a seventh switch transistor T7.

For the sixth switch transistor T6, its gate is the second input terminal 4b of the second output unit 4, its source is the first input terminal 4a of the second output unit 4, and its drain is the first output terminal 4c of the second output unit 4.

For the seventh switch transistor T7, its gate is the second input terminal 4b of the second output unit 4, its source is the first input terminal 4a of the second output unit 4, and its drain is the second output terminal 4d of the second output unit 4.

In implementation, as shown in FIG. 4a, the sixth switch transistor T6 and the seventh switch transistor T7 can be N type transistors, or as shown in FIG. 4b, the sixth switch transistor T6 and the seventh switch transistor T7 can also be P type transistors, which are not limited herein.

The above only exemplarily explains a structure of the second output unit in the shift register unit. In implementation, the structure of the second output unit is not limited to the above structure provided by the embodiment of the present disclosure, but can also be other structures known by those skilled in the art, which is not limited herein.

Optionally, in implementation, in a shift register unit provided by an embodiment of the present disclosure, as shown in FIG. 4a and FIG. 4b, the control unit 5 can comprise an eighth switch transistor T8, a ninth switch transistor T9, a tenth switch transistor T10 and an eleventh switch transistor T11.

For the eighth switch transistor T8, its gate and the gate of the ninth switch transistor T9 are connected both as the input terminal 5a of the control unit 5, its source is connected to the source of the ninth switch transistor T9 and the first DC source VG1 respectively, and its drain is connected to the drain of the tenth switch transistor T10 and is the output terminal 5b of the control unit 5.

The drain of the ninth switch transistor T9 is connected to the gate of the tenth switch transistor 10 and the drain of the eleventh switch transistor T11 respectively.

The source of the tenth switch transistor T10 is connected to the source of the eleventh switch transistor T11, the gate of the eleventh switch transistor T11 and a fourth DC source VG4 respectively.

In implementation, when the first level is a high level, and the second level is a low level, the voltage of the fourth DC source is a high level voltage; when the first level is a low level, and the second level is a high level, the voltage of the fourth DC source is a low level voltage.

In implementation, as shown in FIG. 4a, the eighth switch transistor T8, the ninth switch transistor T9, the tenth transistor T10 and the eleventh switch transistor T11 can be N type transistors, or as shown in FIG. 4b, the eighth switch transistor T8, the ninth switch transistor T9, the tenth transistor T10 and the eleventh switch transistor T11 can also be P type transistors, which are not limited herein.

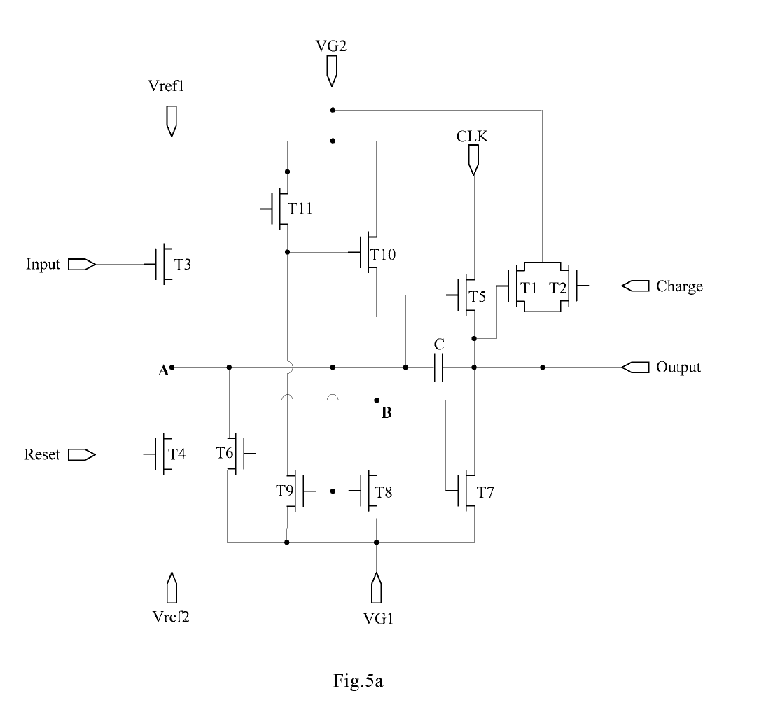

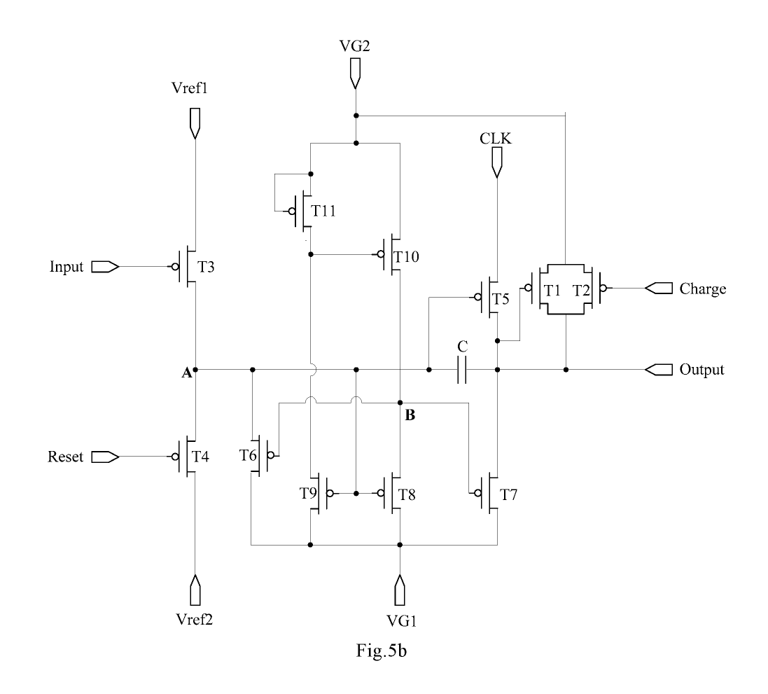

Optionally, in the above shift register unit provided by an embodiment of the present disclosure, as shown in FIG. 5a and FIG. 5b, the second DC source VG2 is the fourth DC source VG4, in other words, the second DC source VG2 and the fourth DC source VG4 are connected to the same power source terminal.

The above only exemplarily explains a structure of the control unit in the shift register unit. In implementation, the structure of the control unit is not limited to the above structure provided by the embodiment of the present disclosure, but can also be other structures known by those skilled in the art, which is not limited herein.

Optionally, in the above shift register unit provided by an embodiment of the present disclosure, the switch transistors usually are transistors with the same material. In implementation, in order to simplify the manufacturing process, all the switch transistors, i.e., the above first to eleventh switch transistors are all P type transistors or N type transistors. When the first to the eleventh switch transistors are all N type transistors, the first level is a high level, the second level is a low level, during forward scan, the first reference voltage is a high level voltage, and the second reference voltage is a low level voltage, and during reverse scan, the first reference voltage is a low level voltage, and the second reference voltage is a high level voltage. When the first to the eleventh switch transistors are all P type transistors, the first level is a low level, the second level is a high level, during forward scan, the first reference voltage is a low level voltage, and the second reference voltage is a high level voltage, and during reverse scan, the first reference voltage is a high level voltage, and the second reference voltage is a low level voltage.

It is noted that the switch transistors mentioned in the above embodiments of the present disclosure can be TFTs (Thin Film Transistors) or can be MOSFETs (Metal Oxide Semiconductor Field Effect Transistors), which is not limited herein. In implementation, the sources and drains of those switch transistors can be exchanged in function depending on different types of transistors and different input signals, which are not distinguished specifically herein.

In the following, by taking the shift register units shown in FIG. 5a and FIG. 5b respectively as examples, their operation processes will be described in detail. In the following description, “1” represents a high level signal, and “0” represents a low level signal.

### First Embodiment

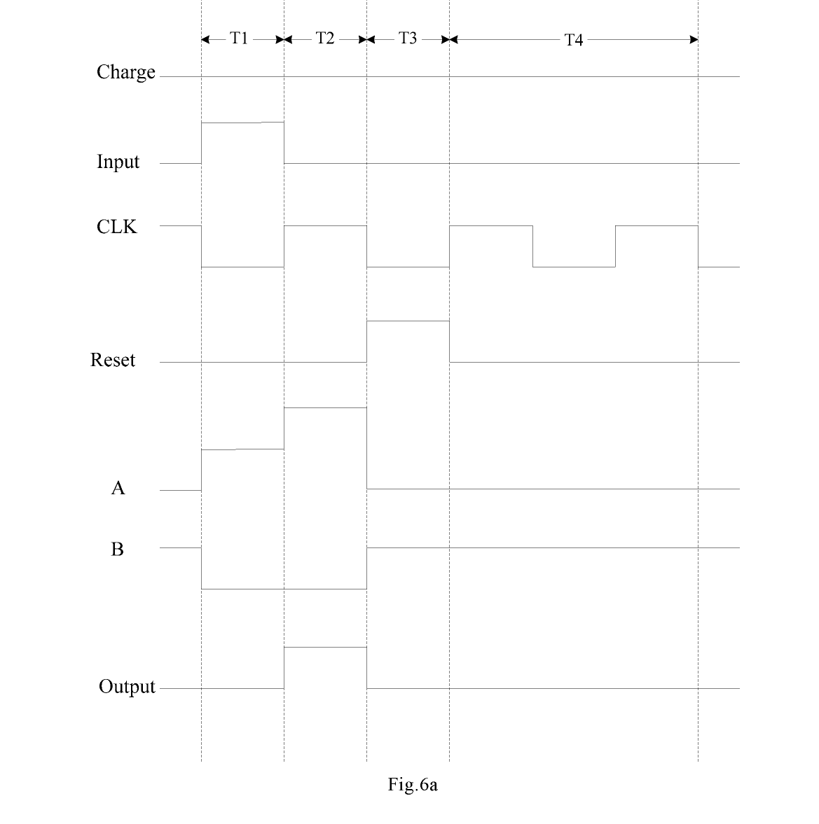

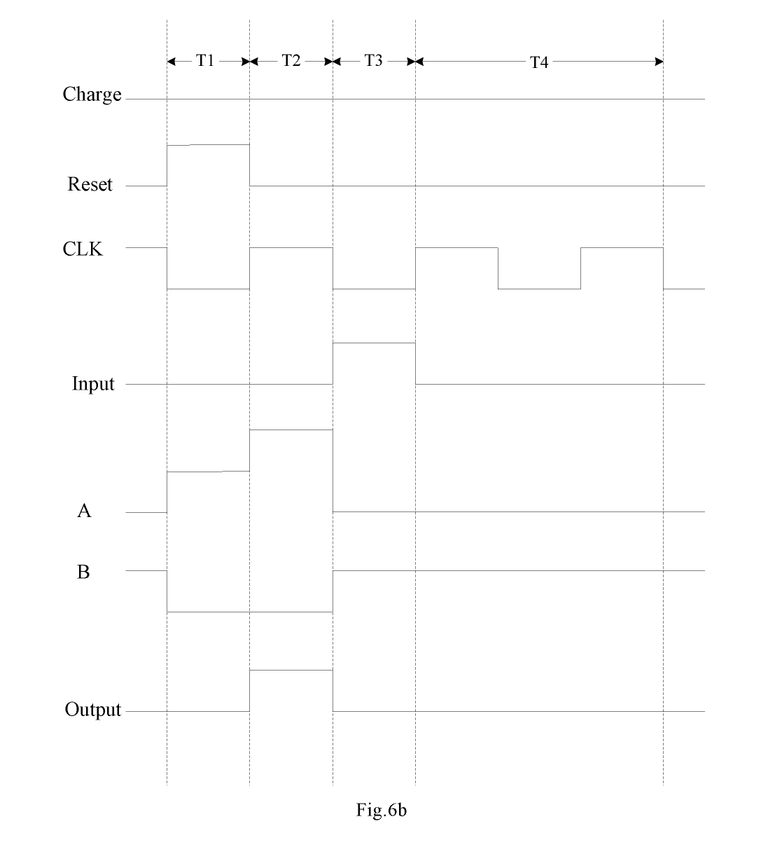

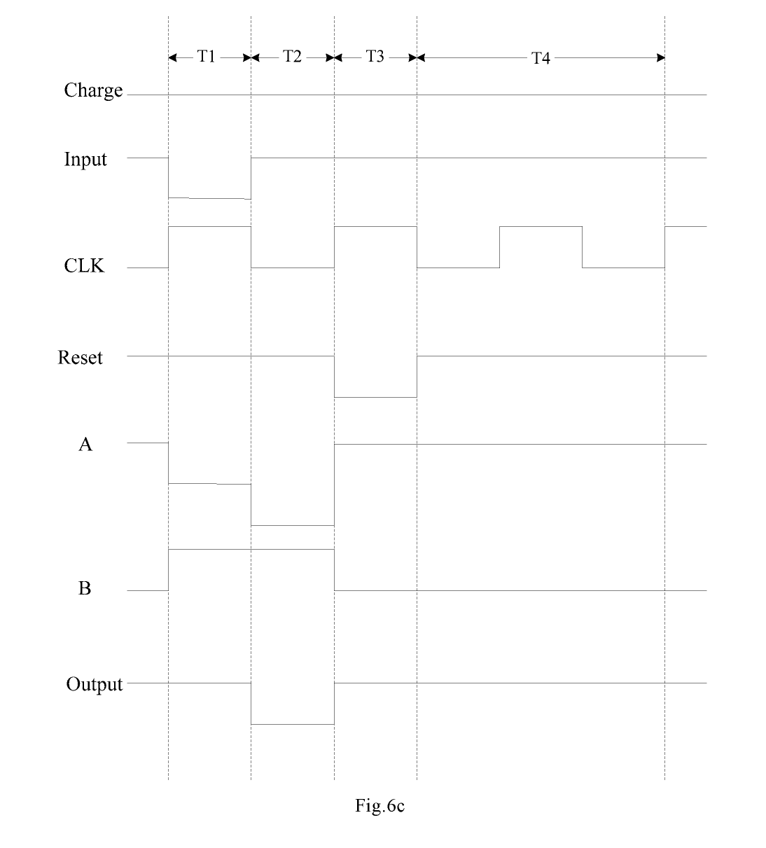

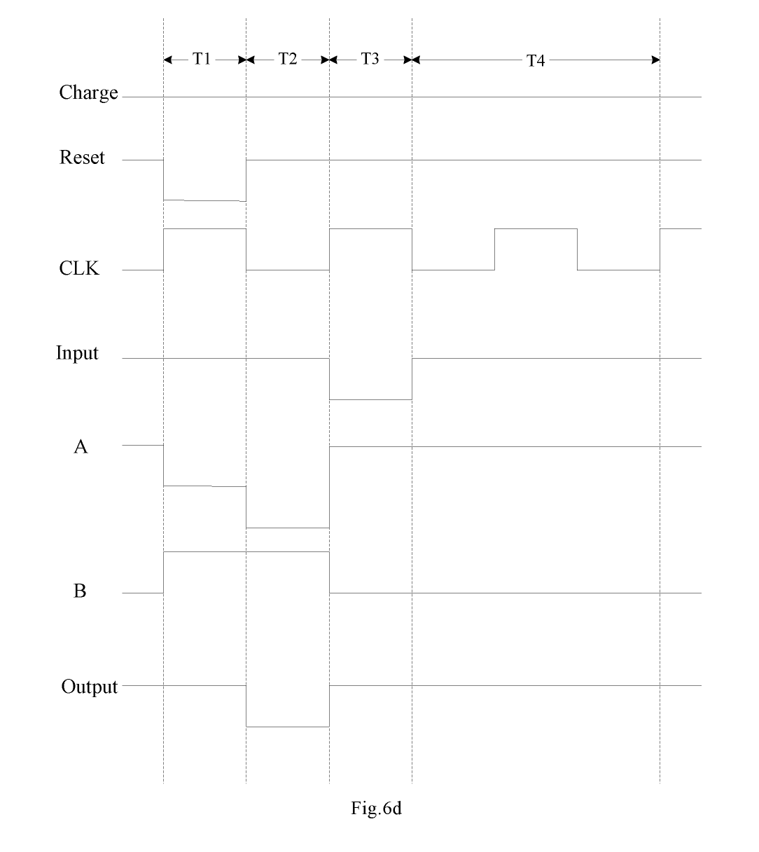

In the shift register unit shown in FIG. 5a, all transistors are N type transistors, and each N type transistor is turned off under the effect of low level and turned on under the effect of high level. During forward scan, the first level is a high level, the second level is a low level, the first reference voltage and the voltage of the second DC source are high level voltages, and the second reference voltage and the voltage of the first DC source are low level voltages. The corresponding input and output time sequence diagram is as shown in FIG. 6a. Four phases of T1, T2, T3 and T4 in the input and output time sequence diagram as shown in FIG. 6a are selected.

At phase T1, Input=1, CLK=0, Reset=0, Charge=0. Since the voltage of the second DC source VG2 is a high level, at the beginning, the tenth switch transistor T10 and the eleventh switch transistor T11 are turned on. Since Input=1, the third switch transistor T3 is turned on, the first reference voltage Vref1 of high level is transferred to the first node A through the third switch transistor T3, and thus the level of the first node A is a high level. The eighth switch transistor T8 and the ninth switch transistor T9 are turned on, such that the tenth switch transistor T10 is turned off and the level of the second node B is a low level. In addition, since the level of the first node A is a high level, the capacitor C starts to be charged, the fifth switch transistor T5 is turned on, and the clock signal CLK of low level is output to the gate signal output terminal Output through the fifth switch transistor T5. Therefore, the gate signal output terminal Output outputs a low level signal.

At phase T2, Input=0, CLK=1, Reset=0, Charge=0. Since CLK=1, the level of the node A is further pulled up according to the effect of the capacitor, and the eighth switch transistor T8 and the ninth switch transistor T9 are turned on, such that the tenth switch transistor T10 is turned off and the level of the second node B is a low level. In addition, since the level of the first node A is a high level, the fifth switch transistor T5 is turned on, and the clock signal CLK of high level is output to the gate signal output terminal Output through the drain of the fifth switch transistor T5. Therefore, the gate signal output terminal Output outputs a high level signal. And, since the level of the drain of the fifth switch transistor T5 is a high level, the first switch transistor T1 is turned on, and the voltage in high level of the second DC source VG2 is transferred to the gate signal output terminal Output through the first switch transistor, effectively reducing distortion of signals output by the gate signal output terminal.

At phase T3, Input=0, CLK=0, Reset=1, Charge=0. Since Reset=1, the fourth switch transistor T4 is turned on, the second reference voltage Vref2 of low level is transferred to the first node A through the fourth switch transistor T4, and thus the level of the first node A becomes a low level. Since the voltage of the second DC source VG2 is a high level, the tenth switch transistor T10 and the eleventh switch transistor T11 are turned on, the level of the second node B is a high level, the sixth switch transistor T6 and the seventh switch transistor T7 are turned on, and the first DC source VG1 of low level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a low level signal.

At phase T4, Input=0, CLK=0 or CLK=1, Reset=0, Charge=0. Since the voltage of the second DC source VG2 is a high level, the tenth switch transistor T10 and the eleventh switch transistor T11 are turned on, the level of the second node B is a high level, the sixth switch transistor T6 and the seventh switch transistor T7 are turned on, and the first DC source VG1 of low level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a low level signal.

The phase T4 is maintained until the next frame comes. The level of the first node A is always a low level, the level of the second node B is always a high level, and the signal output terminal Output always outputs a low level signal, such that the noise of signals output by the signal output terminal Output of the above shift register unit is reduced. In addition, the above shift register unit can also diminish distortion of signals output by the gate signal output terminal, effectively relieving the problem of insufficient charging of high resolution products.

### Second Embodiment

In the shift register unit shown in FIG. 5a, all transistors are N type transistors, and each N type transistor is turned off under the effect of low level and turned on under the effect of high level. During reverse scan, the first level is a high level, the second level is a low level, the second reference voltage and the voltage of the second DC source are high level voltages, and the first reference voltage and the voltage of the first DC source are low level voltages. The corresponding input and output time sequence diagram is as shown in FIG. 6b. Four phases of T1, T2, T3 and T4 in the input and output time sequence diagram as shown in FIG. 6b are selected.

At phase T1, Input=0, CLK=0, Reset=1, Charge=0. Since the voltage of the second DC source VG2 is a high level, at the beginning, the tenth switch transistor T10 and the eleventh switch transistor T11 are turned on. Since Reset=1, the fourth switch transistor T4 is turned on, the second reference voltage Vref2 of high level is transferred to the first node A through the fourth switch transistor T4, and thus the level of the first node A is a high level. The eighth switch transistor T8 and the ninth switch transistor T9 are turned on, such that the tenth switch transistor T10 is turned off and the level of the second node B is a low level. In addition, since the level of the first node A is a high level, the capacitor C starts to be charged, the fifth switch transistor T5 is turned on, and the clock signal CLK of low level is output to the gate signal output terminal Output through the fifth switch transistor T5. Therefore, the gate signal output terminal Output outputs a low level signal.

At phase T2, Input=0, CLK=1, Reset=0, Charge=0. Since CLK=1, the level of the node A is further pulled up according to the effect of the capacitor, and the eighth switch transistor T8 and the ninth switch transistor T9 are turned on, such that the tenth switch transistor T10 is turned off and the level of the second node B is a low level. In addition, since the level of the first node A is a high level, the fifth switch transistor T5 is turned on, and the clock signal CLK of high level is output to the gate signal output terminal Output through the drain of the fifth switch transistor T5. Therefore, the gate signal output terminal Output outputs a high level signal. And, since the level of the drain of the fifth switch transistor T5 is a high level, the first switch transistor T1 is turned on, and the voltage in high level of the second DC source VG2 is transferred to the gate signal output terminal Output through the first switch transistor, effectively reducing distortion of signals output by the gate signal output terminal.

At phase T3, Input=1, CLK=0, Reset=0, Charge=0. Since Input=1, the third switch transistor T3 is turned on, the first reference voltage Vref1 of low level is transferred to the first node A through the third switch transistor T3, and thus the level of the first node A becomes a low level. Since the voltage of the second DC source VG2 is a high level, the tenth switch transistor T10 and the eleventh switch transistor T11 are turned on, the level of the second node B is a high level, the sixth switch transistor T6 and the seventh switch transistor T7 are turned on, and the first DC source VG1 of low level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a low level signal.

At phase T4, Input=0, CLK=0 or CLK=1, Reset=0, Charge=0. Since the voltage of the second DC source VG2 is a high level, the tenth switch transistor T10 and the eleventh switch transistor T11 are turned on, the level of the second node B is a high level, the sixth switch transistor T6 and the seventh switch transistor T7 are turned on, and the first DC source VG1 of low level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a low level signal.

The phase T4 is maintained until the next frame comes. The level of the first node A is always a low level, the level of the second node B is always a high level, and the signal output terminal Output always outputs a low level signal, such that the noise of signals output by the signal output terminal Output of the above shift register unit is reduced. In addition, the above shift register unit can also diminish distortion of signals output by the gate signal output terminal, effectively relieving the problem of insufficient charging of high resolution products.

### Third Embodiment

In the shift register unit shown in FIG. 5b, all transistors are P type transistors, and each P type transistor is turned off under the effect of high level and turned on under the effect of low level. During forward scan, the first level is a low level, the second level is a high level, the first reference voltage and the voltage of the second DC source are low level voltages, and the second reference voltage and the voltage of the first DC source are high level voltages. The corresponding input and output time sequence diagram is as shown in FIG. 6c. Four phases of T1, T2, T3 and T4 in the input and output time sequence diagram as shown in FIG. 6c are selected.

At phase T1, Input=0, CLK=1, Reset=1, Charge=1. Since the voltage of the second DC source VG2 is a low level, at the beginning, the tenth switch transistor T10 and the eleventh switch transistor T11 are turned on. Since Input=0, the third switch transistor T3 is turned on, the first reference voltage Vref1 of high level is transferred to the first node A through the third switch transistor T3, and thus the level of the first node A is a low level. The eighth switch transistor T8 and the ninth switch transistor T9 are turned on, such that the tenth switch transistor T10 is turned off and the level of the second node B is a high level. In addition, since the level of the first node A is a low level, the capacitor C starts to be charged, the fifth switch transistor T5 is turned on, and the clock signal CLK of high level is output to the gate signal output terminal Output through the fifth switch transistor T5. Therefore, the gate signal output terminal Output outputs a high level signal.

At phase T2, Input=1, CLK=0, Reset=1, Charge=1. Since CLK=0, the level of the node A is further pulled down according to the effect of the capacitor, and the eighth switch transistor T8 and the ninth switch transistor T9 are turned on, such that the tenth switch transistor T10 is turned off and the level of the second node B is a high level. In addition, since the level of the first node A is a low level, the fifth switch transistor T5 is turned on, and the clock signal CLK of low level is output to the gate signal output terminal Output through the drain of the fifth switch transistor T5. Therefore, the gate signal output terminal Output outputs a low level signal. And, since the level of the drain of the fifth switch transistor T5 is a low level, the first switch transistor T1 is turned on, and the voltage in low level of the second DC source VG2 is transferred to the gate signal output terminal Output through the first switch transistor, effectively reducing distortion of signals output by the gate signal output terminal.

At phase T3, Input=1, CLK=1, Reset=0, Charge=1. Since Reset=0, the fourth switch transistor T4 is turned on, the second reference voltage Vref2 of high level is transferred to the first node A through the fourth switch transistor T4, and thus the level of the first node A becomes a high level. Since the voltage of the second DC source VG2 is a low level, the tenth switch transistor T10 and the eleventh switch transistor T11 are turned on, the level of the second node B is a low level, the sixth switch transistor T6 and the seventh switch transistor T7 are turned on, and the first DC source VG1 of high level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a high level signal.

At phase T4, Input=1, CLK=1 or CLK=0, Reset=1, Charge=1. Since the voltage of the second DC source VG2 is a low level, the tenth switch transistor T10 and the eleventh switch transistor T11 are turned on, the level of the second node B is a low level, the sixth switch transistor T6 and the seventh switch transistor T7 are turned on, and the first DC source VG1 of high level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a high level signal.

The phase T4 is maintained until the next frame comes. The level of the first node A is always a high level, the level of the second node B is always a low level, and the signal output terminal Output always outputs a high level signal, such that the noise of signals output by the signal output terminal Output of the above shift register unit is reduced. In addition, the above shift register unit can also diminish distortion of signals output by the gate signal output terminal, effectively relieving the problem of insufficient charging of high resolution products.

### Fourth Embodiment

In the shift register unit shown in FIG. 5b, all transistors are P type transistors, and each P type transistor is turned off under the effect of high level and turned on under the effect of low level. During reverse scan, the first level is a low level, the second level is a high level, the second reference voltage and the voltage of the second DC source are low level voltages, and the first reference voltage and the voltage of the first DC source are high level voltages. The corresponding input and output time sequence diagram is as shown in FIG. 6d. Four phases of T1, T2, T3 and T4 in the input and output time sequence diagram as shown in FIG. 6d are selected.

At phase T1, Input=1, CLK=1, Reset=0, Charge=1. Since the voltage of the second DC source VG2 is a low level, at the beginning, the tenth switch transistor T10 and the eleventh switch transistor T11 are turned on. Since Reset=0, the fourth switch transistor T4 is turned on, the second reference voltage Vref2 of low level is transferred to the first node A through the fourth switch transistor T4, and thus the level of the first node A is a low level The eighth switch transistor T8 and the ninth switch transistor T9 are turned on, such that the tenth switch transistor T10 is turned off and the level of the second node B is a high level. In addition, since the level of the first node A is a low level, the capacitor C starts to be charged, the fifth switch transistor T5 is turned on, and the clock signal CLK of high level is output to the gate signal output terminal Output through the fifth switch transistor T5. Therefore, the gate signal output terminal Output outputs a high level signal.

At phase T2, Input=1, CLK=0, Reset=1, Charge=1. Since CLK=0, the level of the node A is further pulled down according to the effect of the capacitor, and the eighth switch transistor T8 and the ninth switch transistor T9 are turned on, such that the tenth switch transistor T10 is turned off and the level of the second node B is a high level. In addition, since the level of the first node A is a low level, the fifth switch transistor T5 is turned on, and the clock signal CLK of low level is output to the gate signal output terminal Output through the drain of the fifth switch transistor T5. Therefore, the gate signal output terminal Output outputs a low level signal. And, since the level of the drain of the fifth switch transistor T5 is a low level, the first switch transistor T1 is turned on, and the voltage in low level of the second DC source VG2 is transferred to the gate signal output terminal Output through the first switch transistor, effectively reducing distortion of signals output by the gate signal output terminal.

At phase T3, Input=0, CLK=1, Reset=1, Charge=1. Since Input=0, the third switch transistor T3 is turned on, the first reference voltage Vref1 of high level is transferred to the first node A through the third switch transistor T3, and thus the level of the first node A becomes a high level. Since the voltage of the second DC source VG2 is a low level, the tenth switch transistor T10 and the eleventh switch transistor T11 are turned on, the level of the second node B is a low level, the sixth switch transistor T6 and the seventh switch transistor T7 are turned on, and the first DC source VG1 of high level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a high level signal.

At phase T4, Input=1, CLK=1 or CLK=0, Reset=1, Charge=1. Since the voltage of the second DC source VG2 is a low level, the tenth switch transistor T10 and the eleventh switch transistor T11 are turned on, the level of the second node B is a low level, the sixth switch transistor T6 and the seventh switch transistor T7 are turned on, and the first DC source VG1 of high level is transferred to the first node A and the gate signal output terminal Output through the sixth switch transistor T6 and the seventh switch transistor T7 respectively, so as to release noises for the first node A and the gate signal output terminal Output. Therefore, the gate signal output terminal Output outputs a high level signal.

The phase T4 is maintained until the next frame comes. The level of the first node A is always a high level, the level of the second node B is always a low level, and the signal output terminal Output always outputs a high level signal, such that the noise of signals output by the signal output terminal Output of the above shift register unit is reduced. In addition, the above shift register unit can also diminish distortion of signals output by the gate signal output terminal, effectively relieving the problem of insufficient charging of high resolution products.

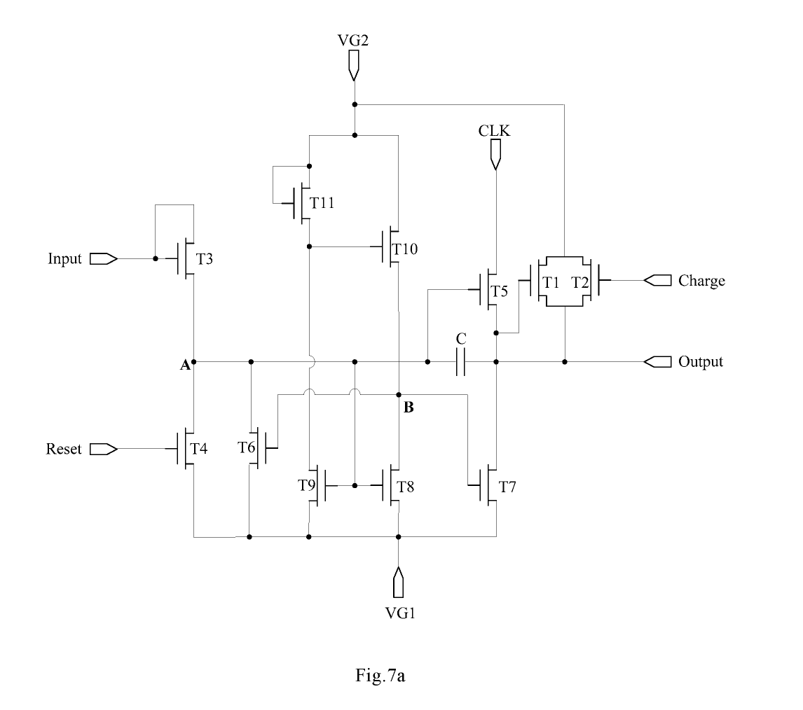

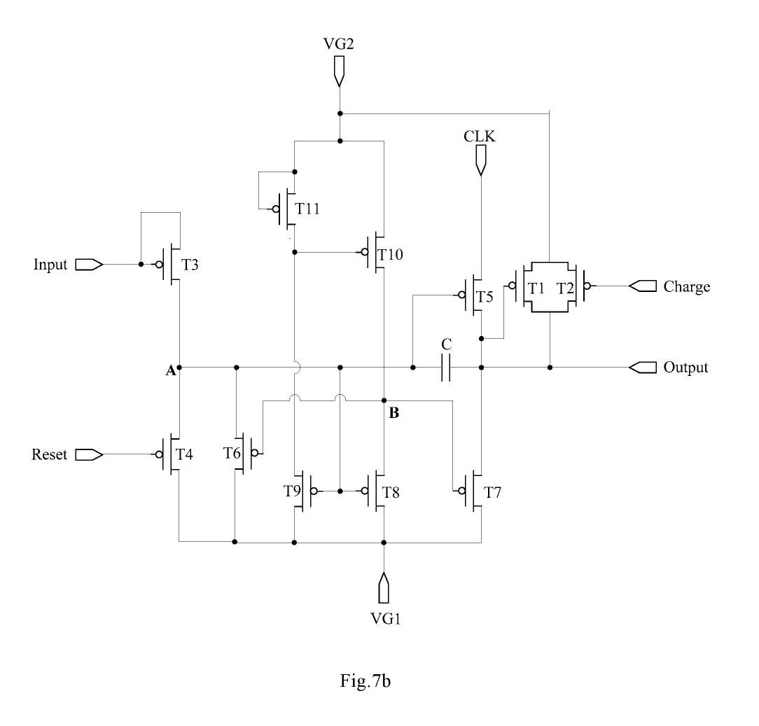

Further, in the above shift register unit provided by an embodiment of the present disclosure, when only unidirectional scan needs to be realized without considering bi-directional scan, as shown in FIG. 7a and FIG. 7b, the first reference voltage Vref1 is replaced by the input signal Input, and the second reference signal Vref2 is replaced by the first DC source VG1, in order to realize forward scan. The operation principle of the forward scan is the same as the principle that the above shift register units as shown in FIG. 5a and FIG. 5b use to realize the forward scan, which will not be repeated here.

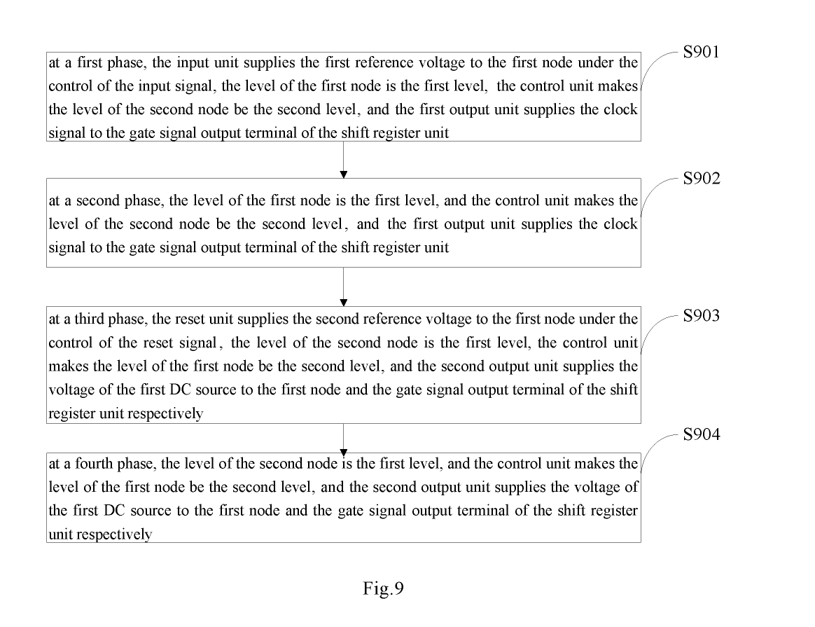

Based on the same disclosed concept, an embodiment of the present disclosure also provides a driving method of any shift register unit as described in the above. FIG. 9 is a schematic flowchart of a driving method of a shift register unit provided by an embodiment of the present disclosure. As shown in FIG. 9, the method comprises the following steps.

In S901, at a first phase, the input unit supplies the first reference voltage to the first node under the control of the input signal; the level of the first node is the first level, and the control unit makes the level of the second node be the second level; the first output unit supplies the clock signal to the gate signal output terminal of the shift register unit.

In S902, at a second phase, the level of the first node is the first level, and the control unit makes the level of the second node be the second level; the first output unit supplies the clock signal to the gate signal output terminal of the shift register unit.

In S903, at a third phase, the reset unit supplies the second reference voltage to the first node under the control of the reset signal; the level of the second node is the first level, and the control unit makes the level of the first node be the second level; the second output unit supplies the voltage of the first DC source to the first node and the gate signal output terminal of the shift register unit respectively.

In S904, at a fourth phase, the level of the second node is the first level, and the control unit makes the level of the first node be the second level; the second output unit supplies the voltage of the first DC source to the first node and the gate signal output terminal of the shift register unit respectively.

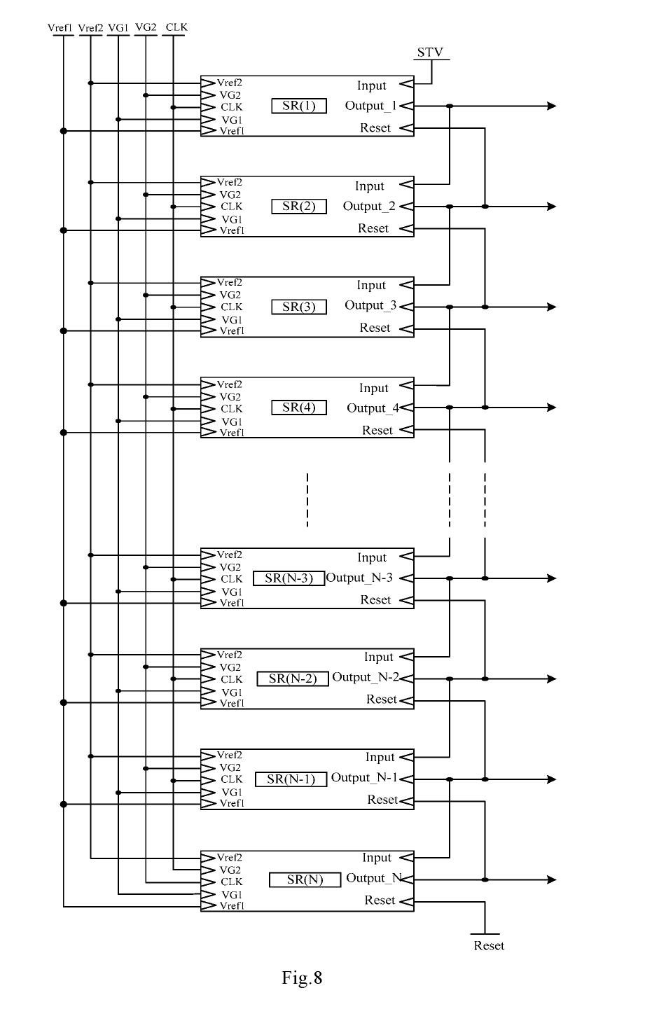

Based on the same disclosed concept, an embodiment of the present disclosure also provides a gate driving circuit. FIG. 8 is a schematic diagram of structure of a gate driving circuit provided by an embodiment of the present disclosure. As shown in Fig.8, the gate driving circuit comprises multiple shift register units of any type described in the above which are connected in series: SR(1), SR(2) . . . SR(n) . . . SR(N−1), SR(N) (totally N shift register units, 1≦n≦N).

Except the first stage of shift register unit SR(1), the gate signal output terminal Output_n (1≦n≦N) of each stage of shift register unit SR(n) inputs a reset signal Reset to its adjacent previous stage of shift register unit SR(n−1).

Except the last stage of shift register unit SR(N), the gate signal output terminal Output_n (1≦n≦N) of each stage of shift register unit SR(n) inputs an input signal Input to its adjacent next stage of shift register unit SR(n+1).

The input signal Input of the first stage of shift register unit SR(1) is input by a frame start signal STV terminal.

Further, in the above gate driving circuit provided by an embodiment of the present disclosure, the clock signal CLK, the first reference voltage Vref1, the second reference voltage Vref2, the first DC voltage source VG1 and the second DC voltage source VG2 are all input into each stage of shift register unit.

Each shift register unit in the above gate driving circuit is the same as the above shift register unit in the present disclosure in function and structure, which will not be repeated here.

In implementation, when the gate driving circuit provided by an embodiment of the present disclosure comprises a discharging unit, during panel test, the discharging units in respective stages of shift register units supply the voltage of the third DC source to the gate signal output terminals of respective stages of shift register units simultaneously under the control of a discharging control signal to output turning-on signals to respective rows of gate lines, so that it is possible to detect whether the pixel units connected to each row of gate line are normal. In addition, it is possible that the discharging units in respective stages of shift register units supply the voltage of the third DC source to the gate signal output terminals of respective stages of shift register units before the display apparatus is shut down to turn on all the gate lines for discharge, effectively relieving the unfavorable problems such as shutdown after-imaging of the display apparatus.

Based on the same disclosed concept, an embodiment of the present disclosure also provides a display apparatus comprising the above gate driving circuit which provides scan signals to gate lines on the array substrate in the display apparatus. The implementation of the display apparatus can refer to the description on the above gate driving circuit. The same points will not be repeated here.

Embodiments of the present disclosure provide a shift register unit, driving method thereof, a gate driving circuit and a display apparatus. The shift register unit comprises an input unit, a reset unit, a first output unit, a second output unit and a control unit. The input unit is configured to supply a first reference voltage to a first node under the control of an input signal; the reset unit is configured to supply a second reference voltage to the first node under the control of a reset signal; the first output unit is configured to supply a clock signal to the gate signal output terminal of the shift register unit when the level of the first node is a first level; the second output unit is configured to supply the voltage of a first DC source to the first node and the gate signal output terminal of the shift register unit respectively when the level of a second node is the first level; the control unit is configured to make the level of the first node be a second level when the level of the second node is the first level and make the level of the second node be the second level when the level of the first node is the first level. The shift register unit uses the control unit to control the levels of the first node and the second node, when the level of the first node is the first level, the first output unit supplies the clock signal to the gate signal output terminal of the shift register unit, and when the level of the second node is the first level, the second output unit supplies the voltage of the first DC source to the first node and the gate signal output terminal of the shift register unit respectively, so as to release noise for the first node and the gate signal output terminal and further ensure that the gate signal output terminal of the shift register unit can always output signals, which can thus eliminate noises and ensure the stability of signals output by the gate signal output terminal.

Obviously, those skilled in the art can make various modifications and variations to the present disclosure without departing from the spirit and the scope of the present disclosure. As such, if those modifications and variations fall within the scope of the claims and their equivalent of the present disclosure, the present disclosure is intended to incorporate those modifications and variations.

What is claimed is:

1. A shift register unit comprising:
an input unit, a first input terminal thereof is configured to receive an input signal, a second input terminal thereof is connected with a first reference voltage and an output terminal thereof is connected to a first node, and which input unit is configured to supply the first reference voltage to the first node under the control of the input signal;
a reset unit, a first input terminal thereof is configured to receive a reset signal, a second input terminal thereof is connected with a second reference voltage and an output terminal thereof is connected to the first node, and which reset unit is configured to supply the second reference voltage to the first node under the control of the reset signal;
a first output unit, a first input terminal thereof is configured to receive a clock signal, a second input terminal thereof is connected to the first node and an output terminal thereof is connected to a gate signal output terminal of the shift register unit, and which first output unit is configured to supply the clock signal to the gate signal output terminal of the shift register unit when the level of the first node is a first level;
a second output unit, a first input terminal thereof is connected to a first DC source, a second input terminal thereof is connected to a second node, a first output terminal thereof is connected to the first node and a second output terminal thereof is connected to the gate signal output terminal of the shift register unit, and which second output unit is configured to supply the voltage of the first DC source to the first node and the gate signal output terminal of the shift register unit respectively when the level of the second node is the first level;
a control unit, an input terminal thereof is connected to the first node and an output terminal thereof is connected to the second node, and which control unit is configured to make the level of the first node be a second level when the level of the second node is the first level and make the level of the second node be the second level when the level of the first node is the first level.

2. The shift register unit according to claim 1, wherein when the first level is a high level and the second level is a low level, the first reference voltage is a high level voltage, and the second reference voltage and the voltage of the first DC source are low level voltages; or when the first level is a low level and the second level is a high level, the first reference voltage is a low level voltage, and the second reference voltage and the voltage of the first DC source are high level voltages.

3. The shift register unit according to claim 1, further comprising a third output unit whose first input terminal is connected to a second DC source, whose second input terminal is connected to the output terminal of the first output unit and whose output terminal is connected to the gate signal output terminal of the shift register unit, and the third output unit being configured to supply the voltage of the second DC source to the gate signal output terminal of the shift register unit when the voltage of the output terminal of the first output unit is the first level.

4. The shift register unit according to claim 3, wherein when the first level is a high level and the second level is a low level, the voltage of the second DC source is a high level voltage; when the first level is a low level and the second level is a high level, the voltage of the second DC source is a low level voltage.

5. The shift register unit according to claim 3, further comprising a discharging unit whose first input terminal is connected to a third DC source, whose second input terminal is connected with a discharging control signal and whose output terminal is connected to the gate signal output terminal, and the discharging unit being configured to supply the voltage of the third DC source to the gate signal output terminal under the control of the discharging control signal.

6. The shift register unit according to claim 5, wherein when the first level is a high level and the second level is a low level, the voltage of the third DC source is a high level voltage; when the first level is a low level and the second level is a high level, the voltage of the third DC source is a low level voltage.

7. The shift register unit according to claim 5, wherein the third output unit comprises a first switch transistor whose gate is the second input terminal of the third output unit, whose source is the first input terminal of the third output unit and whose drain is the output terminal of the third output unit.

8. The shift register unit according to claim 7, wherein the discharging unit comprises a second switch transistor whose gate is the second input terminal of the discharging unit, whose source is the first input terminal of the discharging unit and whose drain is the output terminal of the discharging unit.

9. The shift register unit according to claim 8, wherein the input unit comprises a third switch transistor whose gate is the first input terminal of the input unit, whose source is the second input terminal of the input unit and whose drain is the output terminal of the input unit.

10. The shift register unit according to claim 9, wherein the reset unit comprises a fourth switch transistor whose gate is the first input terminal of the reset unit, whose source is the second input terminal of the reset unit and whose drain is the output terminal of the reset unit.

11. The shift register unit according to claim 10, wherein the first output unit comprise:
a fifth switch transistor whose gate is the second input terminal of the first output unit, whose source is the first input terminal of the first output unit and whose drain is the output terminal of the first output unit; and
a capacitor connected between the gate and the drain of the fifth switch transistor.

12. The shift register unit according to claim 11, wherein the second output unit comprises:
a sixth switch transistor whose gate is the second input terminal of the second output unit, whose source is the first input terminal of the second output unit and whose drain is the first output terminal of the second output unit; and
a seventh switch transistor whose gate is the second input terminal of the second output unit, whose source is the first input terminal of the second output unit and whose drain is the second output terminal of the second output unit.

13. The shift register unit according to claim 12, wherein the control unit comprises:
an eighth switch transistor whose gate is the input terminal of the control unit, whose source is connected to the first DC source and whose drain is the output terminal of the control unit;
a ninth switch transistor whose gate is connected to the gate of the eighth switch transistor and whose source is connected to the source of the eighth switch transistor;
a tenth switch transistor whose gate is connected to a drain of the ninth switch transistor, whose source is connected to a fourth DC source and whose drain is connected to the drain of the eighth switch transistor; and
an eleventh switch transistor whose gate and source are connected to the source of the tenth switch transistor and the fourth DC source and whose drain is connected to the drain of the ninth switch transistor and the gate of the tenth switch transistor.

14. A driving method of the shift register unit according to claim 1, comprising:
at a first phase, the input unit supplying the first reference voltage to the first node under the control of the input signal, the level of the first node being the first level, and the control unit making the level of the second node be the second level, and the first output unit supplying the clock signal to the gate signal output terminal of the shift register unit;
at a second phase, the level of the first node being the first level, and the control unit making the level of the second node be the second level, the first output unit supplying the clock signal to the gate signal output terminal of the shift register unit;
at a third phase, the reset unit supplying the second reference voltage to the first node under the control of the reset signal, the level of the second node being the first level, the control unit making the level of the first node be the second level, the second output unit supplying the voltage of the first DC source to the first node and the gate signal output terminal of the shift register unit respectively; and
at a fourth phase, the level of the second node being the first level, and the control unit making the level of the first node be the second level, the second output unit supplying the voltage of the first DC source to the first node and the gate signal output terminal of the shift register unit respectively.

15. A gate driving circuit comprising multiple shift register units according to claim 1 which are connected in series, wherein
except the first stage of shift register unit, the gate signal output terminal of each stage of shift register unit inputs a reset signal to its adjacent previous stage of shift register unit;
except the last stage of shift register unit, the gate signal output terminal of each stage of shift register unit inputs an input signal to its adjacent next stage of shift register unit; and
the input signal of the first stage of shift register unit is input by a frame start signal terminal.

16. A display apparatus comprise the gate driving circuit according to claim 15.

17. The shift register unit according to claim 1, wherein the input unit comprises a third switch transistor whose gate is the first input terminal of the input unit, whose source is the second input terminal of the input unit and whose drain is the output terminal of the input unit.

18. The shift register unit according to claim 1, wherein the reset unit comprises a fourth switch transistor whose gate is the first input terminal of the reset unit, whose source is the second input terminal of the reset unit and whose drain is the output terminal of the reset unit.

19. The shift register unit according to claim 1, wherein the first output unit comprises:
a fifth switch transistor whose gate is the second input terminal of the first output unit, whose source is the first input terminal of the first output unit and whose drain is the output terminal of the first output unit; and
a capacitor connected between the gate and the drain of the fifth switch transistor.

20. The shift register unit according to claim 1, wherein the second output unit comprises:
a sixth switch transistor whose gate is the second input terminal of the second output unit, whose source is the first input terminal of the second output unit and whose drain is the first output terminal of the second output unit; and
a seventh switch transistor whose gate is the second input terminal of the second output unit, whose source is the first input terminal of the second output unit and whose drain is the second output terminal of the second output unit.
